(19) United States
(12) Patent Application Publication
(10) Pub. No.: US 2014/0299918 A1
(43) Pub. Date: Oct. 9, 2014

(54) SEMICONDUCTOR SUBSTRATE AND FABRICATION METHOD THEREOF, AND SEMICONDUCTOR APPARATUS USING THE SAME AND FABRICATION METHOD THEREOF

(71) Applicant: SK hynix Inc., Gyeonggi-do (KR)

(72) Inventors: Jong Chul LEE, Gyeonggi-do (KR); Min Yong LEE, Gyeonggi-do (KR); Jin Ku LEE, Gyeonggi-do (KR)

(73) Assignee: SK hynix Inc., Gyeonggi-do (KR)

(21) Appl. No.: 13/950,625

(22) Filed: Jul. 25, 2013

(30) Foreign Application Priority Data
Apr. 9, 2013 (KR) 10-2013-0038585

(51) Int. Cl. H01L 21/02; H01L 29/78; H01L 29/66; H01L 29/165

(52) U.S. Cl. CPC H01L 21/02694; H01L 29/165; H01L 29/7841; H01L 29/66431
USPC 257/192; 257/183; 438/508; 438/172

(57) ABSTRACT

A semiconductor substrate and a fabrication method thereof, and a semiconductor apparatus using the same and a fabrication method thereof are provided. The semiconductor substrate includes a semiconductor wafer, a silicon germanium (SiGe)-based impurity doping region formed on the semiconductor wafer, and a protection layer formed on the SiGe-based impurity doping region.

### CROSS-REFERENCES TO RELATED APPLICATION

The present application claims priority under 35 U.S.C. 119(a) to Korean application number 10-2013-0038585, filed on Apr. 9 2013, in the Korean Intellectual Property Office, which is incorporated herein by reference in its entirety.

### BACKGROUND

1. Technical Field

The inventive concept relates to substrate fabrication, and more particularly, to a semiconductor substrate and a fabrication method thereof, and a semiconductor apparatus using the same and a fabrication method thereof.

2. Related Art

Semiconductor apparatuses need to be more highly integrated and highly densified, and various studies on the semiconductor apparatuses with high integration and high density have been made. As an example, switching devices having a vertical structure or a horizontal structure have been developed.

The vertical switching device may ensure sufficient current drivability in a limited channel area. Further, a voltage drop due to an external resistor may be improved through a reduction in a source resistance.

Since the switching device having a horizontal channel structure is configured so that three surfaces of an active region is surrounded by a word line and so that a channel extends to a horizontal direction, memory devices may be fabricated in a stable form. Further, since two switching devices share a source region in a unit active region, and a storage node is configured on a drain region of each of the switching devices, an area efficiency of a memory device configured in a horizontal form may be improved.

Semiconductor apparatuses, specifically, nonvolatile memory devices may be formed so that memory cells connected to one bit line, or all memory cells connected between the word lines and bit lines, share a common source line.

The common source line may be formed by implanting an impurity having a predetermined conductivity type in a semiconductor substrate. As one example, the common source region may be formed by implanting an N-type impurity into a common source line formation region of a silicon substrate formed through an epitaxial growth method and performing a heat treatment.

However, when the heat treatment for diffusing the N-type impurity into the silicon substrate is performed, the N-type impurity is non-uniformly diffused due to a difference in thermal diffusivity of the N-type impurity. Thus, an operational non-uniformity of the memory device results. When a region into which the impurity is not diffused is generated, the common source line is disconnected and thus, the semiconductor apparatus may not normally operate.

FIGS. 1A and 1B illustrate a conventional semiconductor apparatus.

Referring to FIGS. 1A and 1B, a local silicon-on-insulator (SOI) structure, in which a semiconductor layer 103 patterned in a first direction, is formed on a semiconductor substrate 101. The semiconductor layer 103 and the semiconductor substrate 101 are locally insulated by an insulating layer 105.

A gate electrode structure 107, patterned to a direction perpendicular to the first direction, is formed on the local SOI structure. A spacer 109 is formed on facing sidewalls of the gate electrode structure 107.

The gate electrode structure 107 may be a stacked structure including a gate insulating layer 1071, a gate conductive layer 1073 a barrier metal layer 1075, and a hard mask layer 1077.

Next, for example, N-type impurity is implanted to form a common source region 111, a source region 5, and a drain region D.

The semiconductor substrate 101 may be formed through an epitaxial growth method. When a heat treatment process is performed after the impurity for the common source region 111 is implanted, the impurity may be non-uniformly diffused due to the diffusivity of the impurity in the semiconductor substrate 101. If the non-uniform diffusion of the impurity reaches a certain point, a disconnection portion (indicated by “A”) of the common source region 111 may result.

When the impurity are non-uniformly doped in the common source region 111, operation characteristics between unit semiconductor apparatuses may be non-uniform, and fabrication yield of the semiconductor apparatus may be reduced.

### SUMMARY

An exemplary semiconductor substrate may include a semiconductor wafer; a silicon germanium (SiGe)-based impurity doping region formed on the semiconductor wafer; and a protection layer formed on the SiGe-based impurity doping region.

A method of fabricating an exemplary semiconductor substrate may include forming a silicon germanium (SiGe) layer on a semiconductor wafer; forming a protection layer on the SiGe layer; and forming an impurity doping region by implanting an impurity into a predetermined region of the SiGe layer and performing a heat treatment.

An exemplary semiconductor apparatus. The semiconductor apparatus may include a semiconductor substrate including a common source region including a silicon germanium (SiGe) layer doped with impurity; an active region formed on the semiconductor substrate in a first direction, wherein a predetermined portion of the active region is electrically connected to the common source region, and wherein a remaining region of the active region is disposed over the semiconductor substrate as a floating state; a gate structure formed on the active region in a second direction perpendicular to the first direction, wherein the gate structure surrounds an upper surface and both sides of the active region; and a junction region formed in the active region, at both sides of the gate structure.

An exemplary method of fabricating a semiconductor apparatus may include forming a semiconductor substrate by sequentially stacking a semiconductor wafer, a silicon germanium (SiGe) layer, and a protection layer; forming active regions on the semiconductor substrate, the active regions extending along the semiconductor wafer in a first direction, wherein each active region includes a portion that is electrically connected to the semiconductor substrate, and a portion that is disposed over the semiconductor substrate in a floating state; forming an insulating layer on the semiconductor substrate between the active regions, wherein the insulating layer is buried between the semiconductor substrate and a floating portion of each of the active regions forming a gate structure on each of the active regions, the gate structure extending in a second direction perpendicular to the first direction; forming a junction region at both sides of the gate structure in each of the active regions; and forming a common source region in the SiGe layer.

These and other features, aspects, and implementations are described below in the section entitled “DETAILED DESCRIPTION”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIGS. 1A and 1B illustrate a conventional semiconductor apparatus;

FIGS. 2A and 2B are cross-sectional views illustrating an exemplary semiconductor substrate;

FIGS. 3A to 3G are cross-sectional views illustrating a method of fabricating a semiconductor apparatus according to an exemplary implementation of the inventive concept;

FIGS. 4A to 4F are plan views illustrating a method of fabricating an exemplary semiconductor apparatus;

FIG. 5 is a cross-sectional view illustrating a method fabricating an exemplary semiconductor apparatus;

FIG. 6 is a cross-sectional view illustrating a method of fabricating an exemplary semiconductor apparatus; and

FIG. 7 is a graph showing a doping concentration to a doping depth of an N--type impurity, based on a type of a substrate.

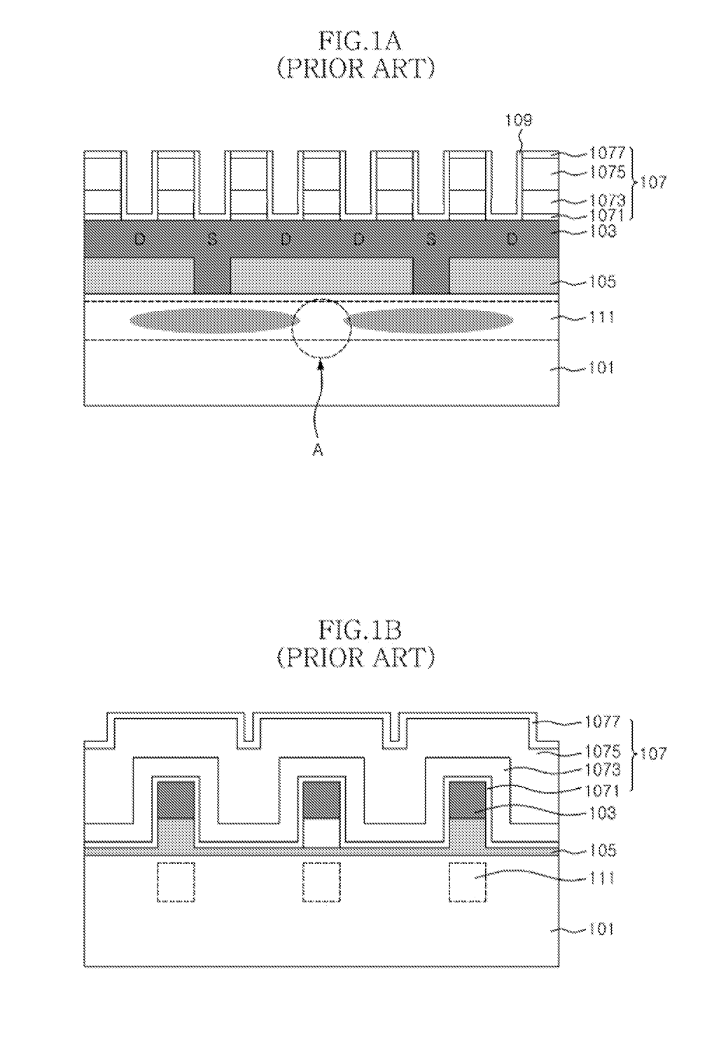

### DETAILED DESCRIPTION

Hereinafter, exemplary implementations will be described in greater detail with reference to the accompanying drawings.

Exemplary implementations are described herein with reference to cross-sectional illustrations that are schematic illustrations of exemplary implementations (and intermediate structures). As such, variations from the shapes of the illustrations as a result, for example, of manufacturing techniques and/or tolerances, are to be expected. Thus, exemplary implementations should not be construed as limited to the particular shapes of regions illustrated herein but may be to include deviations in shapes that result, for example, from manufacturing. In the drawings, lengths and sizes of layers and regions may be exaggerated for clarity. Like reference numerals in the drawings denote like elements. It is also understood that when a layer is referred to as being“on” another layer or substrate, it can be directly on the other or substrate, or intervening layers may also be present.

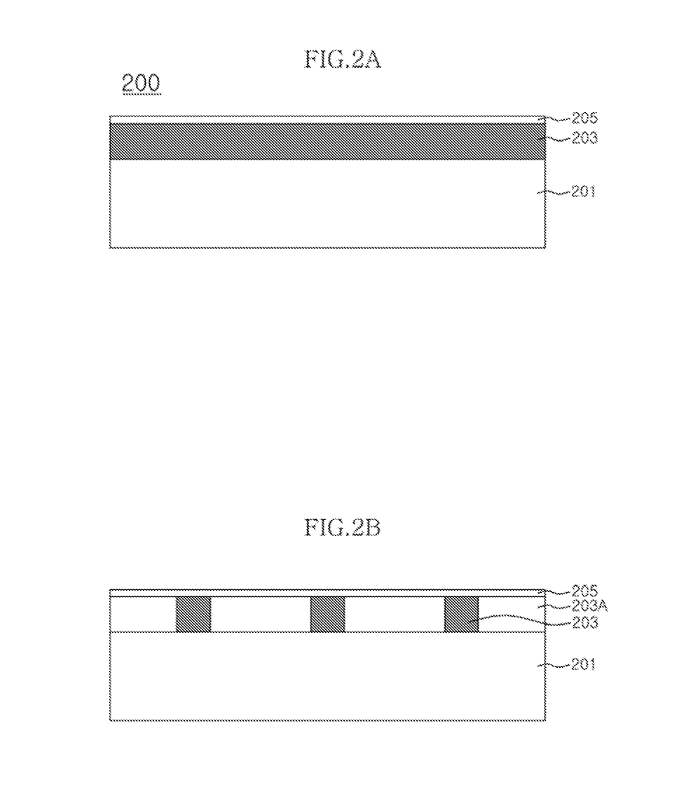

FIGS. 2A and 2B are cross-sectional views illustrating an exemplary semiconductor substrate.

Referring to FIG. 2A, a semiconductor substrate 200 according to an exemplary implementation may include a semiconductor wafer 201, a silicon germanium (SiGe) based impurity doping region 203 formed on a predetermined region of the semiconductor wafer 201, and a protection layer 205 formed on the impurity doping region 203 to cover the semiconductor wafer 201.

The impurity doping region 203 may be formed on an entire surface of the semiconductor wafer 201. In another exemplary implementation, the impurity-doping region 203 may be locally formed on a predetermined region of the semiconductor wafer 201. For example, the impurity-doping region 203 may be locally formed on the semiconductor wafer 201 in a line shape extending with a predetermined width in a first direction.

FIG. 2A is a cross-sectional view in the first direction when the impurity doping region 203 is formed on the entire surface of the semiconductor wafer 201, or when the impurity doping region 203 is formed in a line shape of the first direction. FIG. 2B is a cross-sectional view in a second direction being perpendicular to the first direction when the impurity-doping region 203 is formed in the line shape.

When the impurity-doping region 203 is locally formed as illustrated in FIG, 2B, a SiGe layer 203A may be formed on the semiconductor wafer 201 in which the impurity-doping region 203 is not formed.

The semiconductor wafer 201 may be a silicon substrate formed through an epitaxial growth method.

The impurity doping region 203 may serve as a common source region of memory array formed on the semiconductor substrate in a subsequent process. The impurity doping region 203 may be formed by doping an impurity, for example, an N-type impurity, into the SiGe layer 203A formed through an epitaxial growth method and performing a heat treatment.

The protection layer 205 may be a silicon layer formed through an epitaxial growth method and may prevent the impurity-doping region 203 from being damaged or removed in a subsequent process.

To fabricate the semiconductor substrate 200, the SiGe layer 203A and a protection layer 205 are sequentially formed on the semiconductor wafer 201. Here, the SiGe layer 203A may be formed by an epitaxial silicon growth method and may have a Ge concentration of about 5 wt % to about 30 wt % and a thickness of about 50 Å to about 1000 Å. The protection layer 205 may be formed through an epitaxial growth method to a thickness of about 10 Å to 200 Å.

Next, the impurity-doping region 203 is formed by implanting an impurity in the predetermined region of the SiGe layer 203A and performing a heat treatment. The impurity may be implanted into the SiGe layer 203A in a state in which a region of the SiGe layer 203A that will serve as a common source region is exposed using a mask (not shown). Alternatively, the impurity may be implanted into the entire SiGe layer 203A.

Here, an N-type ion, such as phosphorous (P) or arsenic (As), may be used as the impurity. The N-type ion may be implanted using energy in a range of about 20 KeV to about 80 KeV. The heat treatment may be performed using a rapid thermal annealing (RTA) method. The heat treatment may be performed in a temperature in a range of about 800° C. to about 1200° C. for several seconds to several minutes.

When the N-type impurity is implanted into the SiGe layer 203A and the heat treatment is performed, diffusion speed of the N-type impurity is faster in the SiGe layer than in a Si layer.

Therefore, the common source region having a uniform impurity concentration may be formed in a semiconductor substrate in which a semiconductor apparatus, such as a memory device, is to be formed.

Various semiconductor apparatuses may be fabricated on the semiconductor substrate, as illustrated in FIGS. 2A and 2B, or on a substrate including a stack of undoped wafer/SiGe layer/protection layer. In any one process, from among processes of fabricating a semiconductor apparatus on the stacking substrate of undoped wafer/SiGe layer/protection layer, the common source region may be performed by implanting an impurity into the SiGe layer and performing a heat treatment.

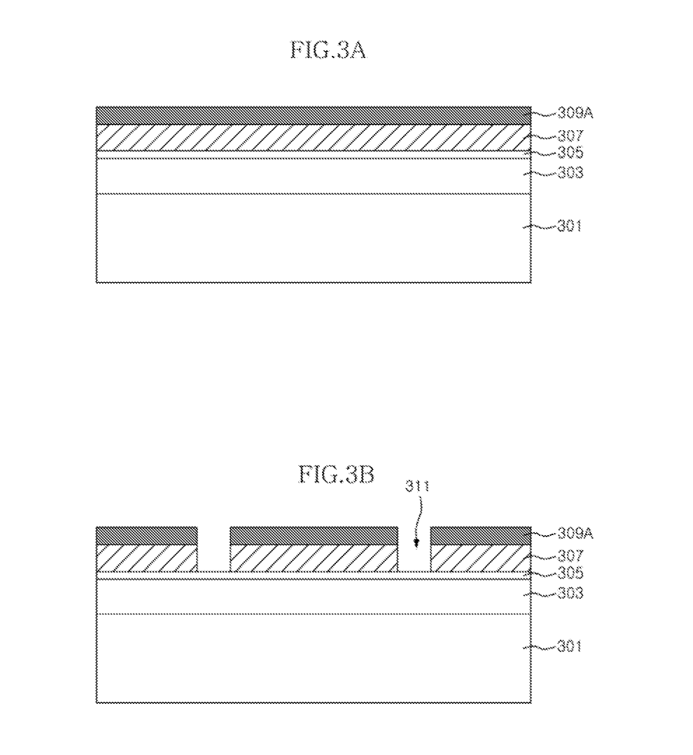

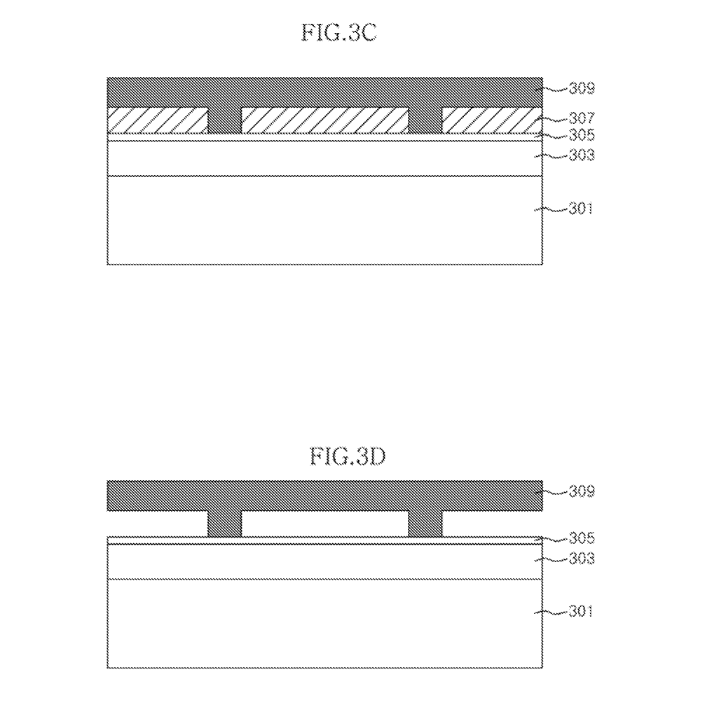

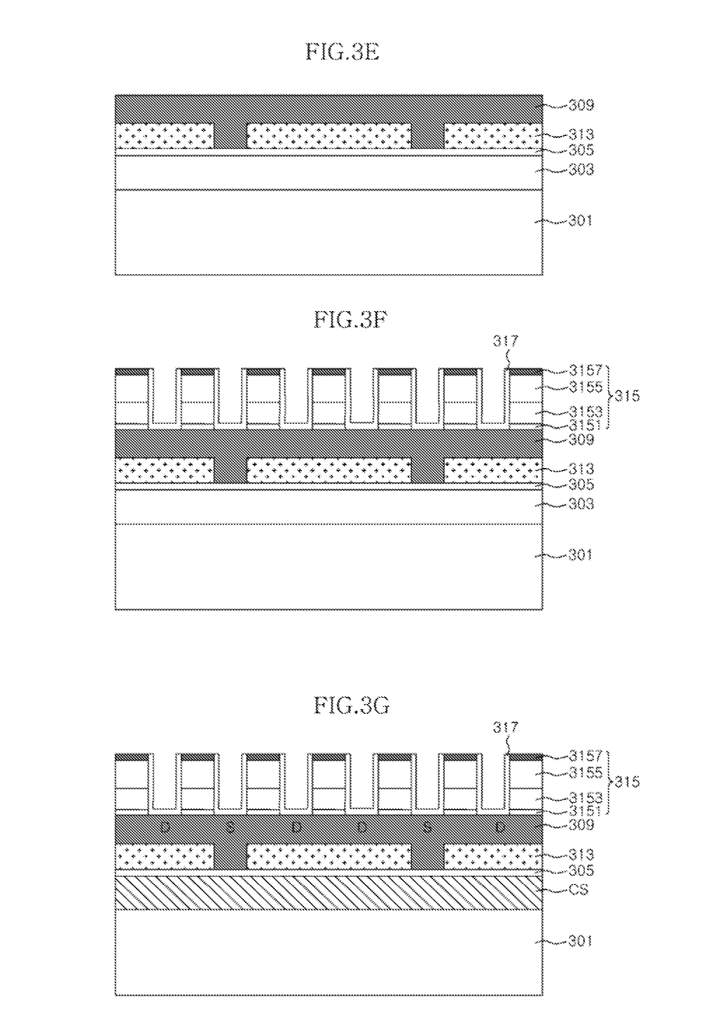

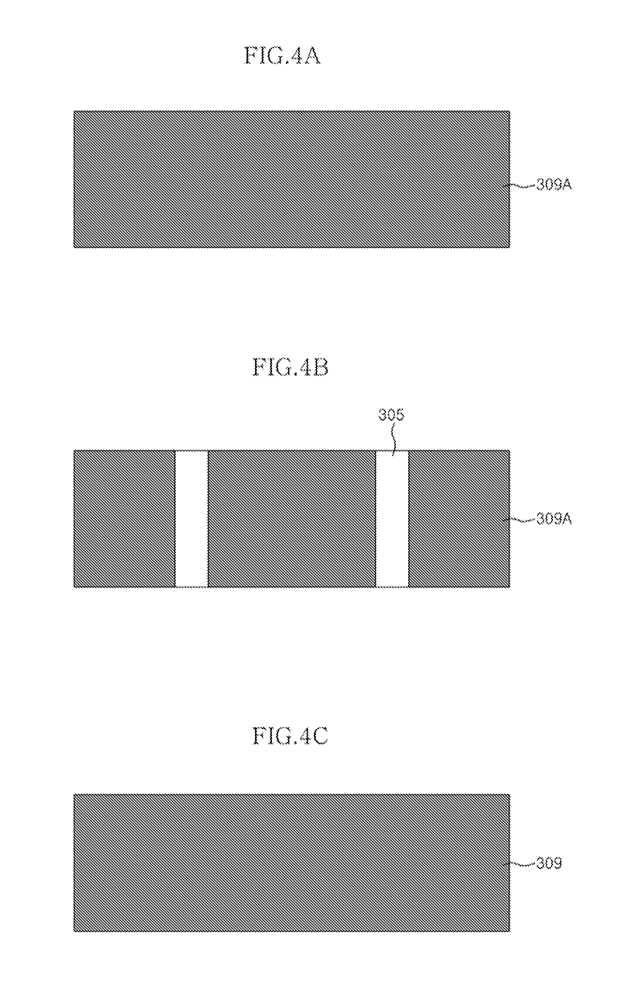

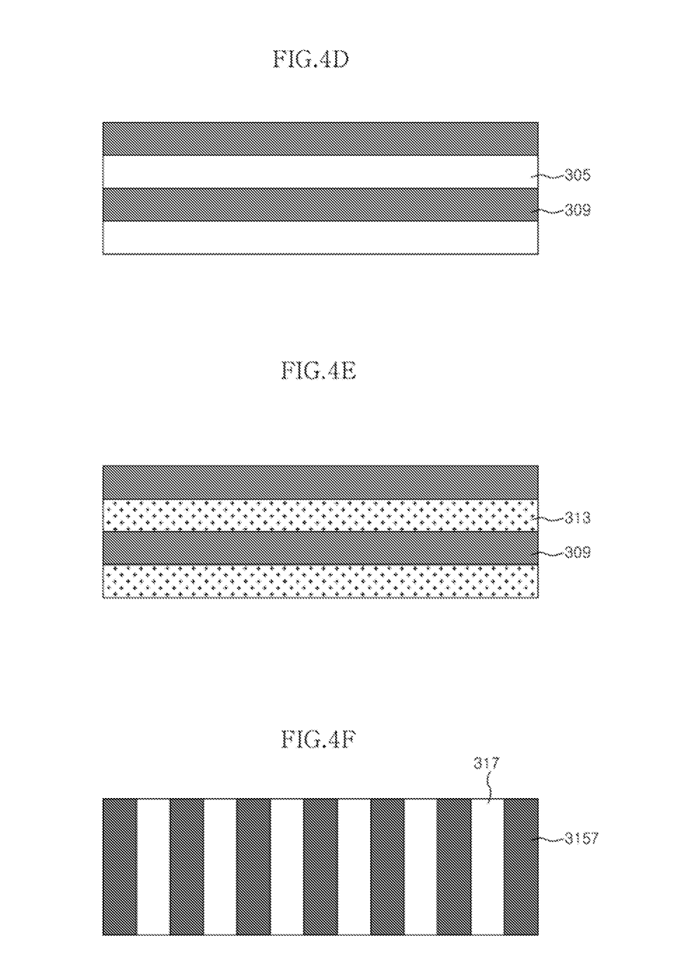

FIGS. 3A to 3G are cross-sectional views illustrating a method of fabricating an exemplary semiconductor apparatus. FIGS. 4A to 4F are plan views illustrating a method of fabricating an exemplary semiconductor apparatus. FIGS. 3A to 3G and FIGS. 4A to 4F illustrate a method of fabricating an exemplary horizontal channel-switching device. However, the invention is not limited thereto.

First, referring to FIGS. 3A and 4A, a semiconductor substrate having a structure in which a semiconductor wafer 301, a SiGe layer 303, and a protection layer 305 are sequentially stacked, is provided. A sacrificial layer 307 and a first semiconductor layer 309A are sequentially stacked on the protection layer 305.

The semiconductor wafer 301 may be a silicon substrate formed through an epitaxial growth method. The SiGe layer 303 may be formed by an epitaxial growth method and may have a Ge concentration of about 5 wt % to about 30 wt % and a thickness of about 50 Å to about 1000 Å. The protection layer 205 may be a Si layer formed by

[symbol]

The SiGe layer 303 serves as a common source region in which an impurity is implanted in a subsequent process. The protection layer 305 may prevent the common source region from being damaged or removed in a subsequent process.

The sacrificial layer 307 and the first semiconductor layer 309A may include semiconductor material layers having different etch selectivity from each other. For example, the sacrificial layer 307 may be formed using SiGe, and the first semiconductor layer 309A may be formed using Si. The sacrificial layer 307 and the first semiconductor layer 309A may be formed through an epitaxial growth method to have a substantially perfect crystalline state.

For example, the sacrificial layer 307 may be formed by an epitaxial growth method and may have a Ge concentration of about 5 wt % to about 30 wt % and a thickness of about 100 Å to about 500 Å. The first semiconductor layer 309A may be formed by an epitaxial growth method to a thickness of about 200 Å to 1000 Å.

Referring to FIGS. 38 and 48, a photoresist pattern (not shown) is formed to expose a predetermined region of the first semiconductor layer 309A. The predetermined region may include a source formation region. The first semiconductor layer 309A and the sacrificial layer 307 are patterned to form a hole 311 that exposes a surface of the protection layer 305.

After the hole 311 is formed, a native oxide layer may be formed. The native oxide layer is completely removed, and a heat treatment is performed at a predetermined temperature and in a hydrogen atmosphere. Therefore, as illustrated in FIGS. 3C and 4C, the first semiconductor layer 309A is flowed to fill the hole 311. To flow the first semiconductor layer 309A, heat treatment process may be used, The first semiconductor layer 309A becomes a second semiconductor layer 309.

Next, referring to FIGS. 3D and 4D, the second semiconductor layer 309 and the sacrificial layer 307 are patterned in a line shape in a direction perpendicular to a formation direction of a gate line (that is, a word line) to be formed in a subsequent process, and active regions (i.e., the line shape pattern of the second semiconductor layer 309) is defined. The sacrificial layer 307 is removed along an exposed side of the active region patterned in the line shape.

Referring to FIGS. 3E and 4E, after the sacrificial layer 307 is removed, an insulating layer 313 is formed on the semiconductor wafer 301 in a space formed by the removal of the sacrificial layer 307. The insulating layer 313 may include a material that can fill the space from which the sacrificial layer 307 was removed. Therefore, the insulating layer 313 may fill the space from which the sacrificial layer 307 was removed and may partially fill a space between the active regions. The insulating layer 313 is recessed so that the insulating layer 313 remains on a surface of the protection layer 305 between the active regions. Therefore, a local silicon-on-insulator (SOI) structure, in which the insulating layer 313 is interposed between the protection layer 305 on the SiGe layer 303 and the second semiconductor layer 309, is formed.

After the local SOI structure is formed, as illustrated in FIGS. 3E and 4E, a word line is formed through a gate formation process. Hereinafter, the SOI structure will be referred to as a bottom structure.

That is, as illustrated in FIGS. 3F and 4F, a gate insulating layer 3151 is formed on the bottom structure, and a gate conductive layer 3153, a barrier metal layer 3155, and a hard mask layer 3157 are sequentially formed on the gate insulating layer 3151. The gate insulating layer 3151, the gate conductive layer 3153, the barrier metal layer 3155, and the hard mask layer 3157 are patterned in a direction perpendicular to the active regions to form a gate structure 315, that is, a word line. A spacer 317 is formed on the second semiconductor layer 309 between the gate structures and on facing sidewalls of the gate structures 315. As illustrated in FIG. 3G, a mask (not shown) is formed on the gate structure 315, and an impurity is implanted in sides of the gate structure 315 to form a source region S, a drain region, and a common source region CS.

The source region S is electrically connected to the common source region CS, and the drain region D is formed on the second semiconductor layer 309 over the insulating layer 313.

To form the common source region CS, an N-type impurity is doped into the SiGe layer 303 and a heat treatment is performed. Here, an N-type ion, such as phosphorous (P) or arsenic (As), may be used as the impurity. T the N-type ion may be implanted using energy in a range of about 20 KeV to about 80 KeV. The heat treatment may be performed using a RTA method. The heat treatment may be performed using a temperature in a range of about 800° C. to about 1200° C. for several seconds to several minutes.

When the N-type impurity is implanted into the SiGe layer 303 and the heat treatment is performed, diffusion speed of the N-type impurity is faster in the SiGe layer than in a Si layer. Therefore, the common source region CS, having a uniform impurity concentration, may be formed.

As described above, a semiconductor apparatus, such as a switching device, may be formed on the semiconductor substrate, in which the common source region is formed in the SiGe layer through an ion implantation process.

As illustrated in FIG. 3G, the formed semiconductor device, that is, the switching structure having a horizontal channel structure may include the semiconductor substrate 301/CS/305, which includes the silicon wafer 301, the common source region CS, which is a SiGe-based impurity doping region, and the protective layer 305, and the second semiconductor layer 309, which is an active region and is formed to extend to the first direction. As discussed above, a predetermined portion of the second semiconductor layer 309 is electrically connected to the semiconductor substrate 301/CS/305. A portion of the second semiconductor layer 309, other than the predetermined portion, is disposed over the semiconductor substrate 301/CS/305 in a floating state. The gate structure 315 is formed on the second semiconductor layer 309 and extends in the second direction perpendicular to the first direction. The gate structure 315 surrounds an upper surface and both sides of the second semiconductor layer 309. Junction regions S and D are formed in the second semiconductor layer 309 at both sides of the gate structure 315. Here, a connection portion of the second semiconductor layer 209 to the semiconductor substrate 301/CS/305 serves as a first junction region. That is, the source region S. An insulating layer 313 is buried in a space between the floating portion of the second semiconductor layer 309 and the semiconductor substrate 301/CS/305. A second junction region, that is, the drain region D, may be formed in a portion of the second semiconductor layer 309 formed on the insulating layer 313. The source region S is electrically connected to the common source region CS (303) through the protection layer 305.

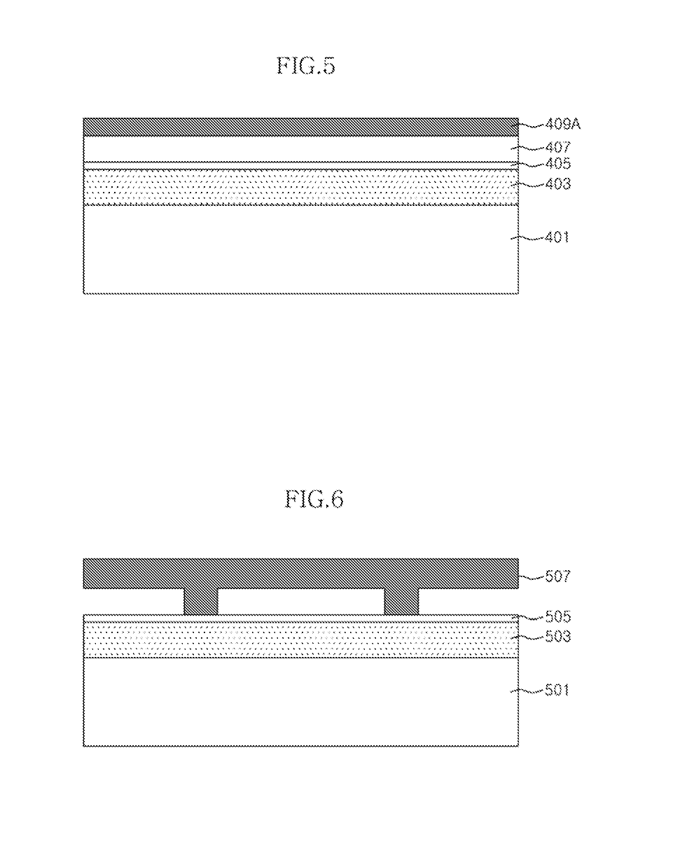

FIG. 5 is a cross-sectional view illustrating a method of fabricating an exemplary semiconductor apparatus.

In an alternative exemplary implementation, a substrate including a semiconductor wafer 401, a common source region 403, and a protection layer 405 is provided. The common source region 403 may be formed by doping an N-type impurity into a SiGe layer, formed through an epitaxial growth method, and performing heat treatment. Next, a sacrificial layer 407 and a first semiconductor layer 409A are sequentially formed on the substrate 400.

Subsequent fabrication processes of the semiconductor apparatus may be the same as or similar to those illustrated in FIGS. 3B to 3G. In the alternative exemplary implementation, since the common source region 403 has been formed before the semiconductor device is formed, the impurity concentration may be more uniformly controlled.

FIG. 6 is a cross-sectional view illustrating a method of fabricating an exemplary semiconductor apparatus.

In an alternative exemplary implementation, a common source region 503 may be formed after an active region is defined. That is, after the active region 309 is defined through the processes illustrated in FIGS. 3A to 3D, the common source region 503 is formed by doping an N-type impurity into a SiGe layer and performing heat treatment.

In FIG. 6, the reference numeral 501 denotes a semiconductor wafer, the reference numeral 505 denotes a protection layer, and the reference numeral 507 denotes a second semiconductor layer.

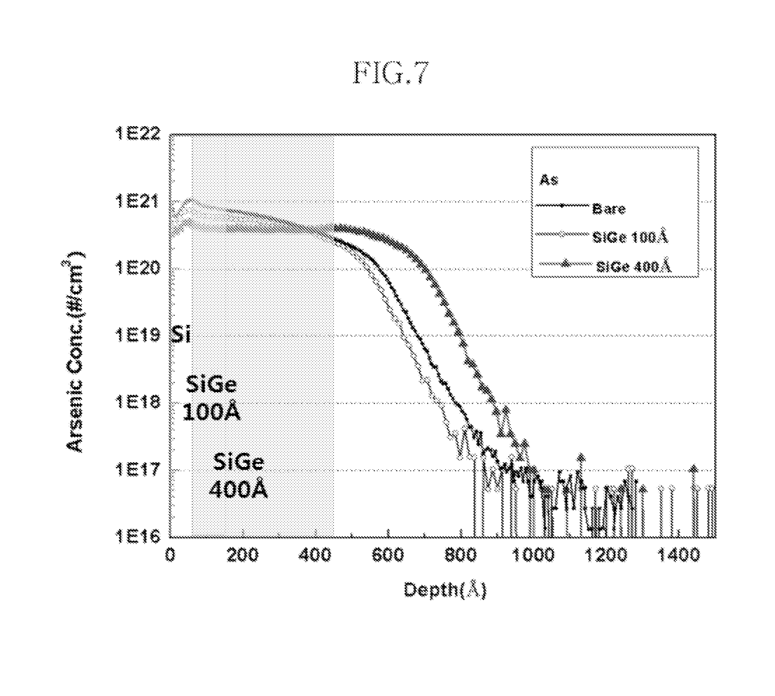

FIG. 7 is a view explaining doping concentration characteristic with respect to a doping depth of an N-type impurity based on a type of substrate. For example, in an experimental example in which As ions are implanted as the N-type impurity. In FIG. 7, a longitudinal axis indicates a concentration of the As ions, and a lateral axis indicates a depth of an entire substrate (a silicon bare substrate or a substrate including wafer/impurity doping region/protection layer.

FIG. 7 shows the behavior of the As ions when an impurity doping region is formed by implanting the As ions into an undoped Si layer and performing heat treatment. FIG. 7 further shows the behavior of the As ions when an impurity doping region, that is, the common source region, is formed by forming a SiGe layer and a Si layer on a semiconductor wafer, implanting the As ions into the SiGe layer, and performing the heat treatment.

It can be seen that when the impurity doping region is formed by implanting the As ions into a bare Si layer and performing heat treatment (indicated by “-•-” in FIG. 7), as the depth is increased, the ion concentration is remarkably lowered, and there is no region in which the ion concentration is uniformly distributed.

It can be seen that when the impurity doping region, that is, the common source region, is formed by implanting the As ions into a SiGe layer with a target of about 100 Å depth from the surface of the SiGe layer, and performing heat treatment (indicated by “-∘-” in FIG. 7), the ion concentration more uniform at a depth of between when compared to the bare silicon layer example. However, the ion concentration becomes non-uniform at a certain depth (more than about 200 Å) or more.

It can be seen that when the impurity doping region, that is, the common source region, is formed by implanting the As ions into the SiGe layer with a target of about 400 A depth from the surface of the SiGe layer, and performing heat treatment (indicated by “-▴-” in FIG. 7), the ion concentration is almost uniform in a doping depth (about 50 to about 600 Å) of the common source region.

It has described that the common source region formed by doping an impurity into the SiGe layer and performing heat treatment is applied to the switching device having a horizontal channel structure. However, but the inventive concept is not limited thereto. The semiconductor substrate of the inventive concept may be applied to any switching device having a horizontal channel structure and all semiconductor devices requiring a common source region.

The above exemplary implementations are illustrative and not limitative. Various alternatives and equivalents are possible. The invention is not limited by the implementation described herein. Nor is the invention limited to any specific type of semiconductor device.

What is claimed is:

1. A semiconductor substrate, comprising:
a semiconductor wafer;
a silicon germanium (SiGe)-based impurity doping region formed on the semiconductor wafer; and
a protection layer formed on the SiGe-based impurity doping region.

2. The semiconductor substrate of claim 1, wherein the SiGe-based impurity doping region is formed on an entire surface of the semiconductor wafer.

3. The semiconductor substrate of claim 1, wherein the SiGe-based impurity doping region is formed on the semiconductor wafer in a line shape extending in a first direction.

4. The semiconductor substrate of claim 3, further comprising:
a plurality of SiGe-based impurity doping regions formed on the semiconductor wafer; and
an undoped SiGe layer formed on the semiconductor wafer between the plurality of SiGe-based impurity doping regions.

5. The semiconductor substrate of claim 1, wherein the semiconductor wafer is a silicon layer formed through an epitaxial growth method, and
the protection layer is a silicon layer formed through an epitaxial growth method.

6. The semiconductor substrate of claim 1, wherein the impurity doping region has a Ge concentration of about 5 wt % to about 30 wt % and a thickness of about 50 Å to about 1000 Å.

7. The semiconductor substrate of claim 6, wherein the protection layer is an epitaxially grown Si layer having a thickness of about 10 Å to about 200 Å.

8. A method of fabricating a semiconductor substrate, the method comprising:
forming a silicon germanium (SiGe) layer on a semiconductor wafer;
forming a protection layer on the SiGe layer; and
forming an impurity doping region by implanting an impurity into a predetermined region of the SiGe layer and performing a heat treatment.

9. The method of claim 8, wherein the forming the SiGe layer comprises:
epitaxially growing the SiGe layer to have a Ge concentration of about 5 wt % to about 30 wt % and a thickness of about 50 Å to about 1000 Å.

10. The method of claim 8, wherein the forming a protection layer comprises:
epitaxially growing a Si layer a thickness of about 10 Å to about 200 Å.

11. The method of claim 8, wherein the planning an impurity further comprises:
implanting the impurity using energy of about 20 KeV to about 80 KeV.

12. The method of claim 8, wherein the performing a heat treatment further comprises:
performing a rapid thermal annealing (RTA) on the impurity doping region at a temperature of about 800° C. to about 1200° C. for several seconds to several minutes.

13. A semiconductor apparatus, comprising:
a semiconductor substrate including a common source region including a silicon germanium (SiGe) layer doped with impurity;
an active region formed on the semiconductor substrate in a first direction, wherein a predetermined portion of the active region is electrically connected to the common source region, and wherein a remaining region of the active region is disposed over the semiconductor substrate as a floating state;
a gate structure formed on the active region in a second direction perpendicular to the first direction, wherein the gate structure surrounds an upper surface and sides of the active region; and
a junction region formed in the active region, at both sides of the gate structure.

14. The semiconductor apparatus of claim 13, wherein the semiconductor substrate includes:
a semiconductor wafer, wherein the common source region is formed on the semiconductor wafer; and
a protection layer formed on the common source region.

15. The semiconductor apparatus of claim 14, wherein the common source region is formed on an entire surface of the semiconductor wafer.

16. The semiconductor apparatus of claim 14, wherein the common source region is formed on the semiconductor wafer in a line shape extending in the first direction.

17. The semiconductor apparatus of claim 16, further comprising:
a plurality of common source regions formed on the semiconductor wafer; and
a SiGe layer formed on the semiconductor wafer between the plurality of common source regions.

18. The semiconductor apparatus of claim 14, wherein the common source region has a Ge concentration of about 5 wt % to about 30 wt % and a thickness of about 50 Å to about 1000 Å.

19. The semiconductor apparatus of claim 18 wherein the protection layer is an epitaxially grown Si layer having a thickness of about 10 Å to about 200 Å.

20. The semiconductor apparatus of claim 1, further comprising:
an insulating layer buried in floating region of the active region, and
wherein the junction regions include:
a first junction region formed in the active region at a portion of the active region that connects to the common source region, and
a second junction region formed in a portion of the active region that is formed on the insulating layer.

21. A method of fabricating a semiconductor apparatus, the method comprising:
forming a semiconductor substrate by sequentially stacking a semiconductor wafer, a silicon germanium (SiGe) layer, and a protection layer;
forming active regions on the semiconductor substrate, the active regions extending along the semiconductor wafer in a first direction, wherein each active region includes a portion that is electrically connected to the semiconductor substrate, and a portion that is disposed over the semiconductor substrate in a floating state;
forming an insulating layer buried between the semiconductor substrate and a floating portion of each of the active regions;
forming a gate structure on each of the active regions, the gate structure extending in a second direction perpendicular to the first direction;
forming a junction region at sides of the gate structure in each of the active regions; and
forming a common source region in the SiGe layer.

22. The method of claim 21, wherein the forming the SiGe layer comprises:
epitaxially growing the SiGe layer to have a Ge concentration of about 5 wt % to about 30 wt % and a thickness of about 50 Å to about 1000 Å.

23. The method of claim 22, wherein the forming a protection layer comprises:
epitaxially growing a Si layer a thickness of about 10 Å to about 200 Å.

24. The method of claim 21, wherein the forming a common source region includes:
implanting an impurity into the Site layer using an energy of about 20 KeV to about 80 KeV; and
performing rapid thermal annealing (RTA) using a temperature of about 800° C. to 1200° C. for several seconds to several minutes.

25. The method of claim 21, wherein the forming of the active regions includes:
sequentially stacking a sacrificial layer and a first semiconductor layer on the semiconductor substrate;
patterning, in the second direction, the first semiconductor layer and the sacrificial layer to form holes exposing a surface of the protection layer to electrically connect each active region to the semiconductor substrate;
forming a second semiconductor layer by flowing the first semiconductor layer to bury the holes;
patterning, in the first direction, the second semiconductor layer o expose the surface of the semiconductor substrate; and
removing the sacrificial layer.
